(19) United States
(12) Patent Application Publication
(10) Pub. No.: US 2021/0082604 A1
(43) Pub. Date: Mar. 18, 2021

(54) SWEPT VERTICAL MAGNETIC FIELD ACTUATION ELECTROMOTIVE DRIVE AND PUMP

(71) Applicant: BOISE STATE UNIVERSITY, Boise, ID (US)

(72) Inventors: Peter Müllner, Boise, ID (US); Ian Varie, Boise, ID (US); Geoffrey Johnston, Boise, ID (US)

(21) Appl. No.: 17/019,748

(22) Filed: Sep. 14, 2020

Related U.S. Application Data
(60) Provisional application No. 62/899,822, filed on Sep. 13, 2019.

(51) Int. Cl. H01F 1/03; H01L 41/12; F04B 43/04

(52) U.S. Cl. CPC H01F 1/0308; F04B 43/043; H01L 41/12

(57) ABSTRACT

A system may include a magnetic shape memory (MSM) element having a first end and a second end, where a longitudinal axis of the MSM element extends from the first end to the second end. The system may further include a permanent magnet having a first pole and a second pole, where the first pole and the second pole are aligned perpendicularly to the longitudinal axis of the MSM element. The system may also include a first electromagnet directed to the first end of the MSM element and a second electromagnet directed to the second end of the MSM element.

### CROSS-REFERENCE TO RELATED APPLICATIONS

This application claims the benefit of, and priority to, U.S. Provisional Patent Application No. 62/899,822, filed on Sep. 13, 2019, and entitled “Swept Vertical Magnetic Field Actuation Electromotive Drive and Pump,” the contents of which are incorporated by reference herein in their entirety.

### FIELD OF THE DISCLOSURE

This disclosure is generally related to the field of magnetic field actuation and, in particular, to a swept vertical magnetic field actuation electromotive drive.

### BACKGROUND

Magnetic shape memory (MSM) alloys may deform strongly when subjected to a variable magnetic field. This deformation may be useful for micro-actuation purposes. For example, MSM elements may be used in micropumps where it is desirable to transmit small volumes (e.g., sub-microliter volumes) of fluid from one location to another, such as delivering small doses of drugs to a subject over a period of time. An MSM micropump may operate by local variations of the magnetic field, thereby reducing a volume of the pump and increasing the energy efficiency of the pump. In other examples, MSM elements may be used for actuating valves, manifolds, or other devices.

Some MSM actuation devices may generate local variations in the magnetic field using a rotating permanent magnet. However, the rotating permanent magnet is typically attached to an external motor via a shaft which must be powered externally and may result in the loss of energy from multiple electrical-mechanical conversions. Further, the additional motor components may be too large for some applications. Also, the additional components may be associated with additional costs.

In some cases, in order to reduce the size and weight of an MSM actuation device, instead of using a permanent magnet for actuation, a set of electromagnetic coils may generate a variable magnetic field. The arrangement of the coils may be simple, such as a linear arrangement. The local magnetic field may be varied by changing the polarity of individual coils. In some cases, the coils may be arranged at angles to generate phase-driven magnetic field rotation. The local magnetic field at an MSM element may be varied by rotating a magnetic field generated by the coils. However, these examples of coil driven devices may need electrical currents that are too high for some applications. If high electrical currents are not provided to the coils, the resulting magnetic field may not be strong enough to result in sufficient deformation of the MSM element. Other disadvantages may exist.

### SUMMARY

Described is a magnetic field actuation system that may use one or more permanent magnets to induce a contracted region within an MSM element while the system is in an unpowered state. The contracted region may result from a vertical component of a magnetic field associated with the one or more permanent magnets. A position of the contracted region may be shifted along the MSM element by powering one or more electromagnets. The power to the electromagnets may be continuously varied to result in a smooth sweeping of the vertical component of the magnetic field, which may cause the contracted region to move from side to side in a continuous motion. The system may not rely on mechanical movement, which may increase the operational life of the system.

In an embodiment, a system includes a magnetic shape memory (MSM) element having a first end and a second end, where a longitudinal axis of the MSM element extends from the first end to the second end. The system further includes a permanent magnet having a first pole and a second pole, where the first pole and the second pole are aligned perpendicularly to the longitudinal axis of the MSM element. The system also includes a first electromagnet directed to the first end of the MSM element and a second electromagnet directed to the second end of the MSM element.

In some embodiments, the system includes one or more magnetic yokes coupled to the permanent magnet, the first electromagnet, and the second electromagnet. In some embodiments, the one or more magnetic yokes are configured to define a first magnetic circuit between the first pole of the permanent magnet to the second pole of the permanent magnet, where the first magnetic circuit passes through the first end of the MSM element and through the first electromagnet. In some embodiments, the one or more magnetic yokes are further configured to define a second magnetic circuit between the first pole of the permanent magnet and the second pole of the permanent magnet, wherein the second magnetic circuit passes through the second end of the MSM element and through the second electromagnet.

In some embodiments, the system includes a controller configured to sweep a first power level through the first electromagnet and to sweep a second power level through the second electromagnet. In some embodiments, the permanent magnet is configured to subject the MSM element to a magnetic field having a predominantly perpendicular component that is perpendicular to the longitudinal axis of the MSM element, wherein sweeping the first power level and the second power level is performed in complement and results in continuous movement of the predominantly perpendicular component along the longitudinal axis of the MSM element. In some embodiments, the MSM element compresses to form a contracted portion of the MSM element in response to local exposure to the predominantly perpendicular component of the magnetic field.

In some embodiments, the system includes a pump housing having a first port and a second port formed within an inner surface of the pump housing, where the MSM element is positioned adjacent to the inner surface of the pump housing and extends from the first port to the second port. In some embodiments, the MSM element includes a Ni—Mn—Ga alloy.

In an embodiment, a system includes an MSM element having a first end and a second end, where a longitudinal axis of the MSM element extends from the first end to the second end. The system further includes a permanent magnet configured to subject the MSM element to a magnetic field. The system also includes a first electromagnet directed to the first end of the MSM element and a second electromagnet directed to the second end of the MSM element. The system includes a controller configured to sweep a first power level through the first electromagnet and to sweep a second power level through the second electromagnet to cause continuous movement of a contracted portion of the MSM element along the longitudinal axis.

In an embodiment, a method includes subjecting an MSM element to a magnetic field of a permanent magnet, where the MSM element has first end, a second end, and a longitudinal axis that extends from the first end to the second end. The method may further include sweeping a first power level through a first electromagnet directed to the first end of the MSM element. The method may also include sweeping a second power level through a second electromagnet directed to the second end of the MSM element.

In some embodiments, the magnetic field has a predominantly perpendicular component that is predominantly perpendicular to the longitudinal axis of the MSM element. In some embodiments, increasing the first power level causes the predominantly perpendicular component of the magnetic field to move toward the second end and decreasing the first power level causes the predominantly perpendicular component to move toward the first end. In some embodiments, increasing the second power level causes the predominantly perpendicular component of the magnetic field to move toward the first end and decreasing the second power level causes the predominantly perpendicular component to move toward the second end. In some embodiments, the first power level and second power level are swept at complementary power levels to cause continuous movement of a contracted portion of the MSM element along the longitudinal axis.

### BRIEF DESCRIPTION OF THE DRAWINGS

FIG. 1 is a perspective representation of an embodiment of a swept vertical magnetic field actuation electromotive drive.

FIG. 2 is a cross-section representation of an embodiment of a swept vertical magnetic field actuation electromotive drive.

FIG. 3 is a cross-section representation of a portion of an embodiment of a swept vertical magnetic field actuation electromotive pump.

FIG. 4A is a cross-section representation of a portion of an embodiment of a swept vertical magnetic field actuation electromotive pump in a first state.

FIG. 4B is a cross-section representation of a portion of an embodiment of a swept vertical magnetic field actuation electromotive pump in a second state.

FIG. 4C is a cross-section representation of a portion of an embodiment of a swept vertical magnetic field actuation electromotive pump in a third state.

FIG. 5A is a graph of a simulated magnetic field generated within an MSM element in a first state.

FIG. 5B is a graph of a simulated magnetic field generated within an MSM element in a second state.

FIG. 5C is a graph of a simulated magnetic field generated within an MSM element in a third state.

FIG. 6 is a graph of an embodiment of a control signal relying on positive polarities for a swept vertical magnetic field actuation electromotive drive.

FIG. 7 is a graph of an embodiment of a control signal relying on positive and negative polarities for a swept vertical magnetic field actuation electromotive drive.

FIG. 8 is a flowchart depicting an embodiment of a method for swept vertical magnetic field actuation.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure.

### DETAILED DESCRIPTION

Examples of micro-actuation using an MSM element and examples of micropumps that operate by local variations in a magnetic field are described in U.S. Pat. No. 9,091,251, filed on Jul. 16, 2012 and entitled “Actuation Method and Apparatus, Micropump, and PCR Enhancement Method,” U.S. Pat. No. 10,408,215, filed on Sep. 23, 2014 and entitled “Electrically Driven Magnetic Shape Memory Apparatus and Method,” U.S. Pat. No. 10,535,457, filed on Mar. 31, 2016 entitled “Electrically Driven Magnetic Shape Memory Apparatus and Method,” and U.S. patent application Ser. No. 16/545,632, filed on Aug. 20, 2019, published as U.S. Patent App. Publication No. 2020/0066965, and entitled “Circular Magnetic Field Generator and Pump,” the contents of each of which are hereby incorporated by reference herein in their entirety. Some traits and properties of the MSM materials and elements described herein may correspond to and be substantially similar to the traits and properties of MSM materials and elements described in the above applications as would be appreciated by persons of skill in the art having the benefit of this disclosure. Likewise, specific traits and properties relating embodiments of a micropump described herein may correspond to and be substantially similar to some traits and properties of micropumps described in the above applications as would be appreciated by persons of skill in the art having the benefit of this disclosure.

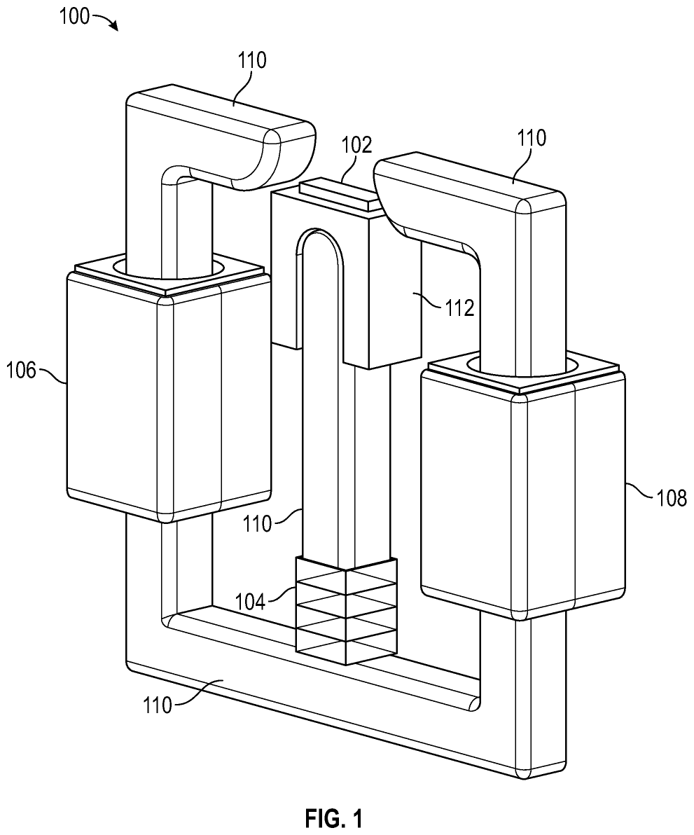

Referring to FIG. 1, an embodiment of a swept vertical magnetic field actuation electromotive drive is depicted as a system 100. The system 100 may include an MSM element 102, a permanent magnet 104, a first electromagnet 106, a second electromagnet 108, and one or more magnetic yokes 110.

The MSM element 102 may be an elongated bar or wire of MSM material. The MSM material may be susceptible to deformation in the presence of a magnetic field. For example, the MSM material may include an alloy such as Nickel-Manganese-Gallium alloy. Based on twinning properties of the MSM material, the MSM element 102 may contract or compress locally in the presence of a predominantly perpendicular component of a magnetic field and may stretch or expand locally in the presence of a substantially parallel component of a magnetic field or in the absence of a magnetic field. As described herein, applying a predominantly perpendicular component of a magnetic field to only a portion of the MSM element 102 may create a neck within the MSM element 102 at that portion. The MSM element 102 may be held between the magnetic yokes 110 by a stand or a podium 112 to enable interaction between the MSM element 102 and the magnetic yokes 110.

The permanent magnet 104 may include magnetized material to produce a constant magnetic field. The one or more magnetic yokes 110 may provide a guided magnetic pathway between the permanent magnet 104 and the podium 112 in order to subject the MSM element 102 to a magnetic field of the permanent magnet 104. The magnetic yokes 110 may include a ferromagnetic material to guide a magnetic field of the permanent magnet 104 and thereby create one or more magnetic circuits as described further herein.

The first electromagnet 106 and the second electromagnet 108 may include any circuits capable of converting electrical power into a magnetic field. For example, the first electromagnet 106 and the second electromagnet 108 may include magnetic coils or solenoids. As shown in FIG. 1, the one or more magnetic yokes 110 may pass through the electromagnets 106, 108 and may direct magnetic fields from the electromagnets 106, 108 to the MSM element 102.

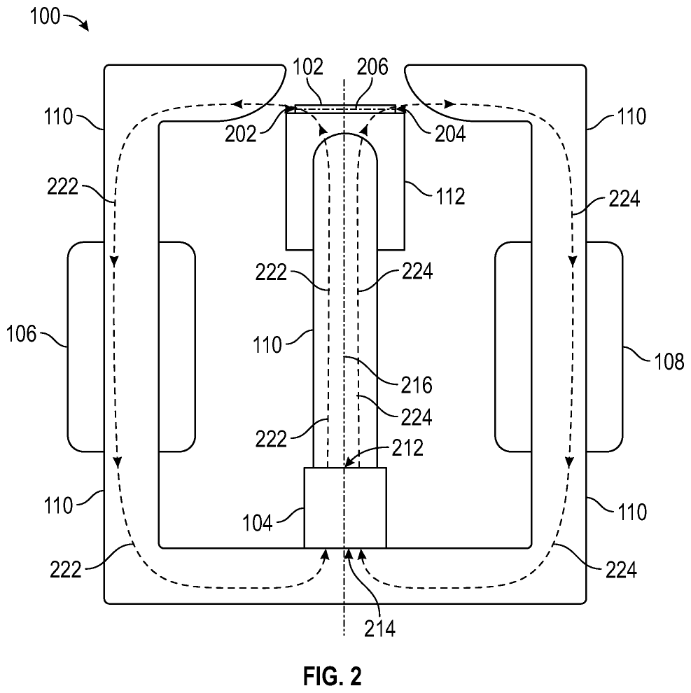

Referring to FIG. 2, an embodiment of a swept vertical magnetic field actuation electromotive drive system 100 is depicted. FIG. 2 is a cross-section taken from FIG. 1. In FIG. 2, the electromagnets 106, 108 are depicted as solid. However, in practice the electromagnets 106, 108 may include electrical loops or coils (not shown) that, when powered, may generate magnetic fields. The MSM element 102 may have a first end 202 and a second end 204. A longitudinal axis 206 may pass through the MSM element lengthwise from the first end 202 to the second end 204.

The permanent magnet 104 may be directed toward the MSM element 102. In other words, the permanent magnet 104 may have a first magnetic pole 212 and a second magnetic pole 214. An axis 216 may run through the permanent magnet 104 passing through the first magnetic pole 212 and the second magnetic pole 214. The axis 216 may intersect the longitudinal axis 206 of the MSM element 102 perpendicularly. Thus, when neither the first electromagnet 106 nor the second electromagnet 108 are powered, the permanent magnet 104 may produce a magnetic field having a component that is predominantly perpendicular to the MSM element 102 at a center of the MSM element 102. The magnetic yoke 110 may direct the magnetic field from the permanent magnet 104 to the MSM element 102. FIG. 2 shows that the axis 216 may intersect the longitudinal axis 206 at a center of the MSM element 102. However, the system 100 may be designed such that the permanent magnet 104 is not positioned in the center between the electromagnets 106, 108 such that the axis 216 intersects the longitudinal axis 204 of the MSM element not in the center of the element (in an asymmetrical configuration). For clarity, the magnetic field has not been illustrated in FIG. 2 and is further described herein.

As seen in FIG. 2, the one or more magnetic yokes 110 may define a first magnetic circuit 222 starting near the first magnetic pole 212 of the permanent magnet 104 and circling around to the second magnetic pole 214 of the permanent magnet 104. The first magnetic circuit 222 may pass through the first end 202 of the MSM element 102 and through the first electromagnet 106. Likewise, the one or more magnetic yokes 110 may define a second magnetic circuit 224 starting near the first magnetic pole 212 of the permanent magnet 104 and circling around to the second magnetic pole 214 of the permanent magnet 104. The second magnetic circuit 224 may pass through the second end 204 of the MSM element 102 and through the second electromagnet 108. Although the magnetic circuits 222, 224 are depicted as passing in a particular direction (upward through the podium 112 and downward through the electromagnets 106, 108) in practice the polarity of the permanent magnet 104 may be up or down, as would be understood by persons of skill in the art having the benefit of this disclosure.

As stated above, when the electromagnets 106, 108 are unpowered, a perpendicular component of the magnetic field (relative to the longitudinal axis 206 of the MSM element 102) may be directed at a center of the MSM element 102 (or elsewhere along the MSM element in the case of an asymmetrical configuration). Powering the first electromagnet 106 may strengthen a magnetic draw along the first magnetic circuit 222 and shift the perpendicular component to the right along the MSM element 102. Likewise, powering the second electromagnet 108 may strengthen a magnetic draw along the second magnetic circuit 224 and shift the perpendicular component to the left along the MSM element 102.

As stated above, the perpendicular component may affect the MSM material of the MSM element 102 to create a compressed portion or neck in the MSM element 102. By shifting the perpendicular component of the magnetic field, the compressed portion or neck may be moved left or right as controlled by the electromagnets 106, 108. Thus, electromotive actuation may be enabled at the MSM element 102.

A benefit of the system 100 is that the MSM element 102 may be actuated without mechanical movement as opposed to other actuation systems that may rely on a rotating permanent magnet. Further, the majority of the strength of the magnetic field may be provided by the permanent magnet 104 while the electromagnets 106, 108 may be used for simply shifting the magnetic field of the stronger permanent magnet 104. Thus, the system 100 may use less power than other actuation systems that may rely on electric coils alone to generate a magnetic field for actuation. Other benefits may exist.

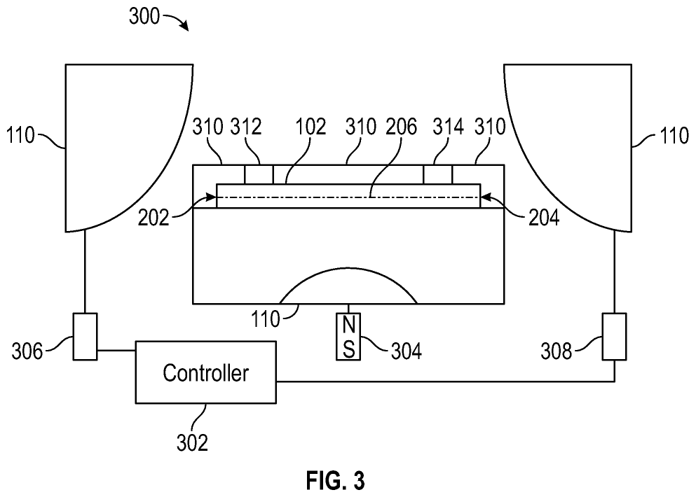

Referring to FIG. 3, an embodiment of a swept vertical magnetic field actuation electromotive pump system 300 is depicted. The system 300 may correspond to the system 100 with the inclusion of a pump housing 310. Further, FIG. 3, only illustrates a portion of the system 300 surrounding the MSM element 102, where the remaining components that are not shown in FIG. 3 may be the same as depicted in FIGS. 1 and 2.

FIG. 3 depicts a permanent magnet polarity 304, a first electromagnet polarity 306, and a second electromagnet polarity 308. The permanent magnet polarity 304 may be associated with the permanent magnet 104 (depicted in FIGS. 1 and 2). The first electromagnet polarity 306 may be associated with the first electromagnet 106 and the second electromagnet polarity 308 may be associated with the second electromagnet 108. In FIG. 3, both the first electromagnetic polarity 306 and the second electromagnetic polarity 308 are neutral (meaning both the electromagnets 106, 108 are unpowered). The permanent magnetic polarity 304 is depicted as having a north magnetic pole on top and a south magnetic pole at the bottom. Thus, in FIG. 3, only the permanent magnet is subjecting the MSM element 102 to a magnetic field.

The system 300 may include a controller 302 for controlling the electromagnetic polarities 306, 308. Although FIG. 3 is described in terms of polarity, the controller 302 may be configured to control a range of magnetic strengths as well. The controller 302 may include any type of circuitry or processing elements to produce control signals for the electromagnets 106, 108. Types of circuitry may include switches, amplifiers, modulators, demodulators, and the like. Types of processing elements may include a central processing unit (CPU), a digital signal processor (DSP), a peripheral interface controller (PIC), and/or another type of processing element.

The pump housing 310 may include a first port 312 and a second port 314 defined herein. The ports 312, 314 may be openings within the pump housing 310 used for fluid inlets and/or outlets. The MSM element 102 may be positioned within the pump housing 310 with the first end 202 of the MSM element 102 being associated with the first port 312 the second end 204 of the MSM element 102 being associated with the second port 314. The MSM element 102 may be positioned adjacent to an inner surface of the pump housing 310 in order to block fluid between the first port 312 and the second port 314.

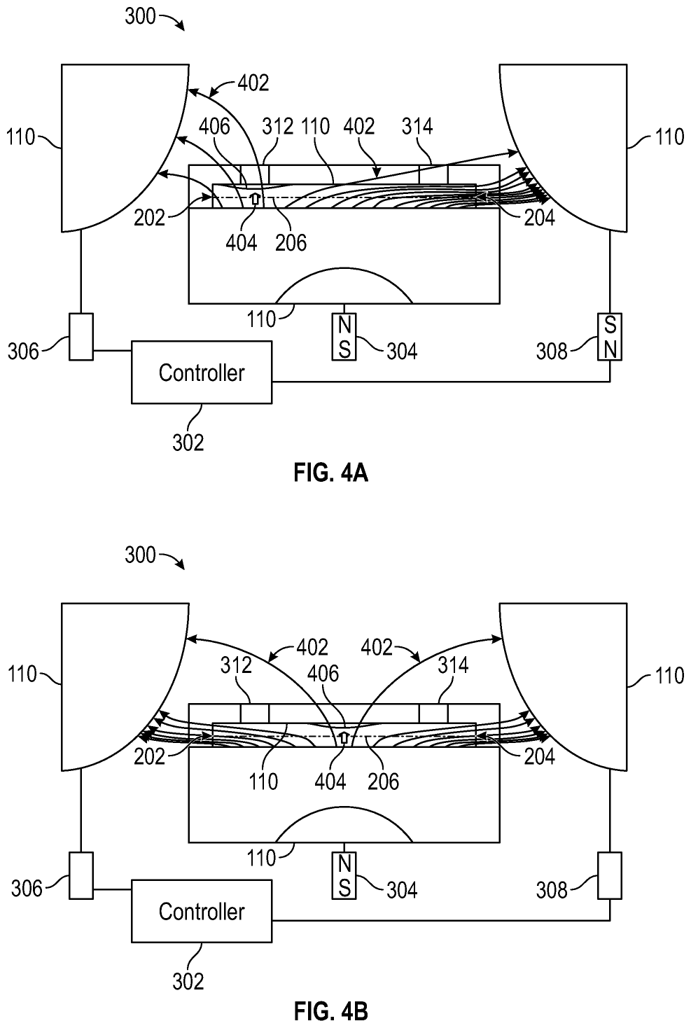

Referring to FIG. 4A, the embodiment of the swept vertical magnetic field actuation electromotive pump system 300 is depicted in a first state. In the first state, the permanent magnet polarity 304 may be north-south (having a north pole at the top and a south pole at the bottom). The controller 302 may send control signals such that the first electromagnetic polarity 306 may be neutral and the second electromagnetic polarity 308 may be south-north (having a south pole at the top and a north pole at the bottom). A resulting magnetic field 402 is illustrated and may be pulled toward the second electromagnetic polarity 308 through the one or more magnetic yokes 110. The shift in the magnetic field may cause a predominantly perpendicular component 404 of the magnetic field 402 to be positioned near the first end 202 of the MSM element 102. As shown in FIG. 4A the remainder of the magnetic field 402 may be substantially parallel to the longitudinal axis 206 of the MSM element 102.

The predominantly perpendicular component 404 of the magnetic field 402 may cause the MSM element 102 to compress near the first end 202 resulting in a compressed portion or neck 406 to form underneath the first port 312. In some applications, the compressed portion or neck 406 may receive a fluid therein to be transported to the second port 314.

Referring to FIG. 4B, a portion of an embodiment of a swept vertical magnetic field actuation electromotive pump system 300 is depicted in a second state. In the second state, the permanent magnet polarity 304 may be north-south as before. The controller 302 may send control signals such that both the first electromagnetic polarity 306 and the second electromagnetic polarity 308 may be neutral.

The resulting magnetic field 402 may be equally distributed between the first and second electromagnetic polarities 306, 308. Thus, the predominantly perpendicular component 404 of the magnetic field 402 may be positioned in the middle of the MSM element 102. The remainder of the magnetic field 402 (positioned away from the middle of the MSM element 102) may be substantially parallel to the longitudinal axis 206 of the MSM element 102. The compressed portion or neck 406 may also move to the middle of the MSM element 102 away from the first end 202 and the first port 312 and toward the second end 204 and the second port 314. The transition within the second electromagnetic polarity 308 may be based on a continuous change in strength or intensity such that the compressed portion or neck 406 may move continuously along the MSM element carrying any fluid that may have come from the first port 312 with it.

Referring to FIG. 4C, a portion of an embodiment of a swept vertical magnetic field actuation electromotive pump system 300 is depicted in a third state. In the third state, the permanent magnet polarity 304 is unchanged. The controller 302 may send control signals such that the first electromagnetic polarity 306 may have a south-north polarity and the second electromagnetic polarity 308 may be neutral.

The resulting magnetic field 402 may be pulled toward the first electromagnetic polarity 306 through the one or more magnetic yokes 110. The shift in the magnetic field 402 may cause the predominantly perpendicular component 404 of the magnetic field 402 to shift to a position near the second end 204 of the MSM element 102. The remainder of the magnetic field 402 may be substantially parallel to the longitudinal axis 206 of the MSM element 102. Thus, the compressed portion or neck 406 may also move toward the second end 204 of the MSM element 102. As before, the transition within the first electromagnetic polarity 306 may be based on a continuous change in strength or intensity such that the compressed portion or neck 406 may move continuously along the MSM element carrying any fluid that may have come from the first port 312 with it. The fluid may then be released through the second port 314.

As illustrated in FIGS. 4A-4C, the compressed portion or neck 406 may be moved continuously along the MSM element 102. In particular, the movement may be applied to a pump as shown to pump fluid from the first port 312 to the second port 314. This may be performed by using the controller to sweep a first power level through the first electromagnet 106 and to sweep a second power level through the second electromagnet 108. Further, in some applications, the controller 302 may generate signals to move the compressed portion or neck 406 in either direction along the MSM element 102 or to pause movement, depending on the particular application. Other benefits may exist.

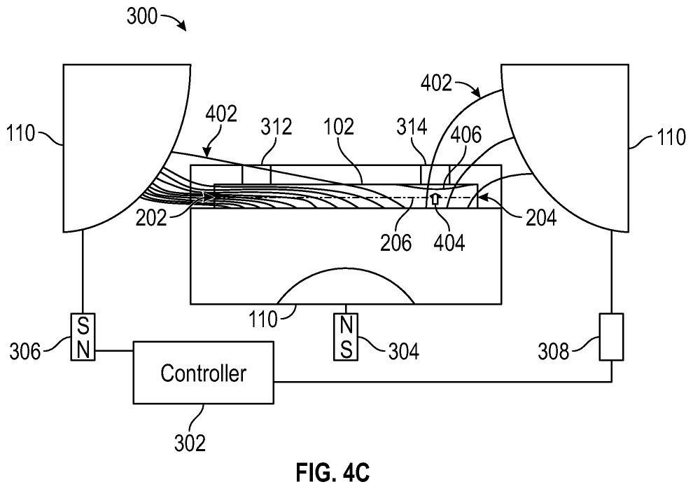

Referring to FIG. 5A, a graph of a simulated magnetic field generated within the MSM element 102 is depicted in the first state. The configuration in FIG. 5A may correspond to the configuration described with respect to FIG. 4A. The magnetic field may be predominantly perpendicular to the MSM element at the left side of the MSM element when the electromagnet on the right is activated and draws the magnetic field toward it. As shown, the magnetic field may be predominantly parallel to the MSM element elsewhere within the MSM element.

Referring to FIG. 5B, a graph of a simulated magnetic field generated within the MSM element 102 is depicted in a second state. The configuration in FIG. 5B may correspond to the configuration described with respect to FIG. 4B. The magnetic field may be predominantly perpendicular to the MSM element in the middle of the MSM element when the electromagnets on both the right and the left are inactive. As shown, the magnetic field may be predominantly parallel to the MSM element elsewhere.

Referring to FIG. 5C is a graph of a simulated magnetic field generated within the MSM element 102 is depicted in a third state. The configuration in FIG. 5A may correspond to the configuration described with respect to FIG. 4C. The magnetic field may be predominantly perpendicular to the MSM element at the right side of the MSM element when the electromagnet on the left is activated and draws the magnetic field toward it. As shown, the magnetic field may be predominantly parallel to the MSM element elsewhere within the MSM element.

As shown in the simulations of FIGS. 5A-5B, a predominantly perpendicular component of a magnetic field may be swept along an MSM element using the setup depicted in FIGS. 1-4B. By adjusting the power individually at each electromagnet and continuously sweeping the magnetic field, actuation in the form of a movable compressed portion or neck in the MSM element may be achieved.

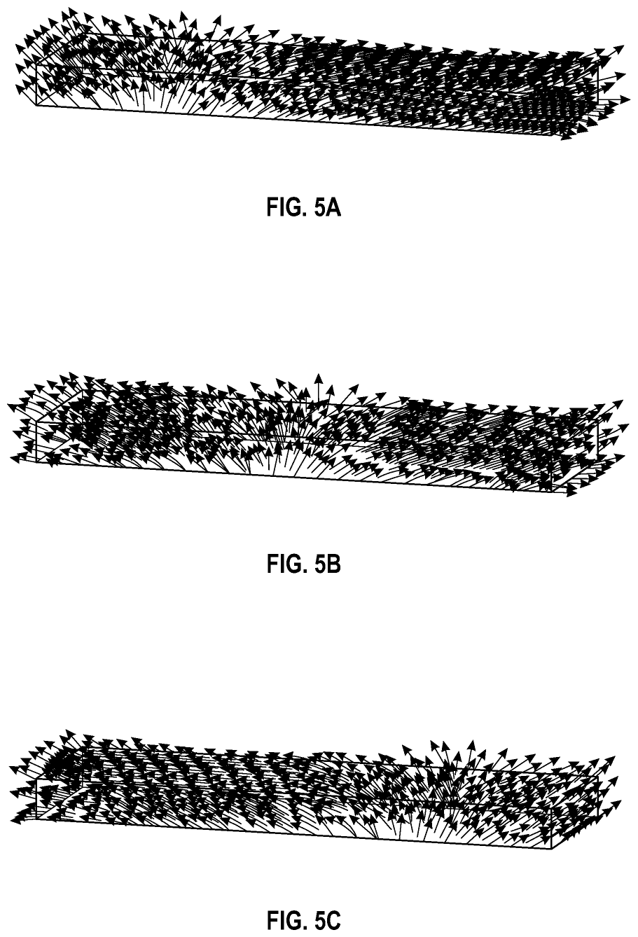

Referring to FIG. 6, an embodiment of control signals for the first electromagnet 106 and the second electromagnet 108 are depicted. The control signals may vary as a voltage over time. In FIG. 6, the voltage is represented on the vertical axis while time is represented on the horizontal axis. Although the control signals are described in terms of voltage, the strength of the electromagnets 106, 108 may rely on other parameters, such as current or field intensity. Further, in FIG. 6, the control signals may include positive polarities, meaning the voltage remains positive and the polarity of the electromagnets 106, 108 does not change. Other configurations are also possible.

A first control signal 606 may control an intensity of a magnetic field produced by the first electromagnet 106. A second control signal 608 may control an intensity of a magnetic field produced by the second electromagnet 108. At time TA, the first control signal 606 may be 0 volts putting the first electromagnet in a neutral state. The second control signal 608 may be at a voltage VMAX, which may power the second electromagnet. Thus, the time TA may correspond to the state depicted in FIG. 4A. In that state, the first electromagnetic 106 is neutral and the second electromagnet 108 is powered, which results in the predominantly perpendicular component 404 of the magnetic field 402 being positioned near the first end 202 of the MSM element 102.

As time progresses, the second control signal 608 may diminish continuously until both the first control signal 606 and the second control signal 608 are zero at time TB. At time TB, both the electromagnets 106, 108 may be in a neutral state. The time TB may correspond to the state depicted in FIG. 4B. In that state, the predominantly perpendicular component of the magnetic field may be positioned in the middle of the MSM element 102. The continuous sweeping of the second control signal 608 may result in the gradual movement of the predominantly perpendicular component 404. Thus, the compressed portion or neck 406 may also move gradually toward the middle of the MSM element 102.

As time continues, the first control signal 606 may increase continuously until the first control signal 606 reaches VMAX and the second control signal 608 is zero at time TC. At time TC, the first electromagnet 106 may be powered and the second electromagnet 108 may be in a neutral state. The time TC may correspond to the state depicted in FIG. 4B, where the predominantly perpendicular component 404 of the magnetic field 402 is positioned near the second end 204 of the MSM element 102.

As shown in FIG. 6, the first power signal 608 (or power level) may be swept through the first electromagnet 106 and the second power signal 606 (or power level) may be swept through the second electromagnet 108. Sweeping the first power signal 606 and the second power signal 608 level may be performed in complement (as shown by the symmetry in FIG. 6), resulting in continuous movement of the predominantly perpendicular component 404 along the full length of the MSM element 102.

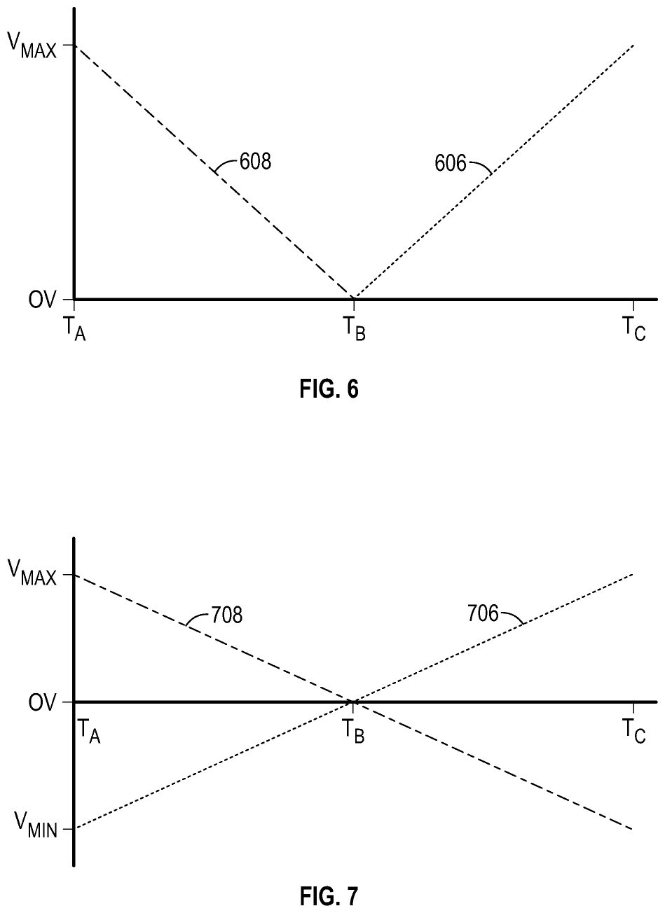

Referring to FIG. 7, another embodiment of a control signal is depicted. In FIG. 7, the control signals may rely on both positive and negative polarities. For example, at time TA, a first control signal 706 may be at a negative voltage VMIN and the second control signal 708 may be at a positive voltage VMAX. In this way, the second electromagnet 108 may draw the magnetic field 402 toward it while the first electromagnet 106 pushed the magnetic field 402 away. While this particular embodiment is not depicted in FIG. 4A, it can be seen that, depending on the strength of the permanent magnet 104, a negative polarity in the first electromagnet 106 may be useful in shaping the magnetic field 402.

As time progresses, the second control signal 708 may diminish continuously and the first control signal 706 may increase until both the first control signal 706 and the second control signal 608 are zero at time TB. At time TB, both the electromagnets 106, 108 may be in a neutral state. The time TB of FIG. 7 may correspond to the state depicted in FIG. 4B. In that state, the predominantly perpendicular component of the magnetic field may be positioned in the middle of the MSM element 102.

As time continues, the first control signal 706 may increase continuously and the second control signal 708 may decrease until the first control signal 706 reaches VMAX and the second control signal 608 reaches VMIN at time TC. At time TC, the first electromagnet 106 may be powered and the second electromagnet 108 may also be powered in a reverse polarity. As before, the predominantly perpendicular component 404 of the magnetic field 402 may be positioned near the second end 204 of the MSM element 102 with the additional aid of the second electromagnet 108.

FIGS. 6 and 7 depict examples of control signals that may be used. However, the disclosure is not limited only to these patterns. The control signals may be switched to reverse a direction of the actuation within the MSM element 102. The control signals may be user controlled to provide precise control of the location of the actuation. Different wave structures may be used, such as sinusoidal or sawtooth. Diverse control signals may be used providing for a wide range of applications.

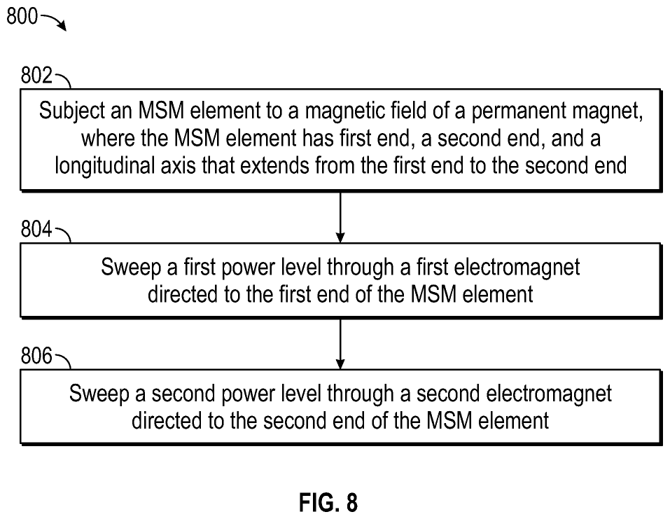

Referring to FIG. 8, an embodiment of a method 800 for swept vertical magnetic field actuation is depicted. The method 800 may include subjecting an MSM element to a magnetic field of a permanent magnet, where the MSM element has first end, a second end, and a longitudinal axis that extends from the first end to the second end, at 802. For example, the one or more magnetic yokes 110 may subject the MSM element 102 to the magnetic field 402 produced at least in part by the permanent magnet 104.

The method 800 may further include sweeping a first power level through a first electromagnet directed to the first end of the MSM element, at 804. For example, the first power signal 606 may be swept through the first electromagnet 106 and the one or more magnetic yokes 110 may direct the first electromagnet 106 to the first end 202 of the MSM element 102.

The method 800 may also include sweeping a second power level through a second electromagnet directed to the second end of the MSM element, at 806. For example, the second power signal 608 may be swept through the second electromagnet 108 and the one or more magnetic yokes 110 may direct the second electromagnet 108 to the second end 204 of the MSM element 102.

The first power level and second power level may be swept at complementary power levels to cause continuous movement of a contracted portion of the MSM element 102 along the longitudinal axis 206. This may enable actuation to occur without movable parts and at lower power levels than other micro-actuation devices. Other benefits may exist.

Although various embodiments have been shown and described, the present disclosure is not so limited and will be understood to include all such modifications and variations as would be apparent to one skilled in the art.

What is claimed is:

1. A system comprising:
a magnetic shape memory (MSM) element having a first end and a second end, wherein a longitudinal axis of the MSM element extends from the first end to the second end;
a permanent magnet having a first pole and a second pole, wherein the first pole and the second pole are aligned perpendicularly to the longitudinal axis of the MSM element;
a first electromagnet directed to the first end of the MSM element; and
a second electromagnet directed to the second end of the MSM element.

2. The system of claim 1, further comprising one or more magnetic yokes coupled to the permanent magnet, the first electromagnet, and the second electromagnet.

3. The system of claim 2, wherein the one or more magnetic yokes are configured to define a first magnetic circuit between the first pole of the permanent magnet to the second pole of the permanent magnet, wherein the first magnetic circuit passes through the first end of the MSM element and through the first electromagnet.

4. The system of claim 3, wherein the one or more magnetic yokes are further configured to define a second magnetic circuit between the first pole of the permanent magnet and the second pole of the permanent magnet, wherein the second magnetic circuit passes through the second end of the MSM element and through the second electromagnet.

5. The system of claim 1, wherein the MSM element includes a Ni—Mn—Ga alloy.

6. The system of claim 1, further comprising a controller configured to sweep a first power level through the first electromagnet and to sweep a second power level through the second electromagnet.

7. The system of claim 6, wherein the permanent magnet is configured to subject the MSM element to a magnetic field having a predominantly perpendicular component that is perpendicular to the longitudinal axis of the MSM element, wherein sweeping the first power level and the second power level is performed in complement and results in continuous movement of the predominantly perpendicular component along the longitudinal axis of the MSM element.

8. The system of claim 7, wherein the MSM element compresses to form a contracted portion of the MSM element in response to local exposure to the predominantly perpendicular component of the magnetic field.

9. The system of claim 1, further comprising a pump housing having a first port and a second port formed within an inner surface of the pump housing, wherein the MSM element is positioned adjacent to the inner surface of the pump housing and extends from the first port to the second port.

10. A system comprising:
a magnetic shape memory (MSM) element having a first end and a second end, wherein a longitudinal axis of the MSM element extends from the first end to the second end;
a permanent magnet configured to subject the MSM element to a magnetic field;
a first electromagnet directed to the first end of the MSM element;
a second electromagnet directed to the second end of the MSM element; and
a controller configured to sweep a first power level through the first electromagnet and to sweep a second power level through the second electromagnet to cause continuous movement of a contracted portion of the MSM element along the longitudinal axis.

11. The system of claim 10, further comprising one or more magnetic yokes coupled to the permanent magnet, the first electromagnet, and the second electromagnet.

12. The system of claim 11, wherein the one or more magnetic yokes are configured to define a first magnetic circuit between a first pole of the permanent magnet and a second pole of the permanent magnet, wherein the first magnetic circuit passes through the first end of the MSM element and through the first electromagnet.

13. The system of claim 12, wherein the one or more magnetic yokes are further configured to define a second magnetic circuit between the first pole of the permanent magnet and the second pole of the permanent magnet, wherein the second magnetic circuit passes through the second end of the MSM element and through the second electromagnet.

14. The system of claim 10, wherein the magnetic field has a predominantly perpendicular component that is perpendicular to the longitudinal axis of the MSM element, wherein the contracted portion is formed in response to the predominantly perpendicular component of the magnetic field.

15. The system of claim 10, further comprising a pump housing having a first port and a second port formed within an inner surface of the pump housing, wherein the MSM element is positioned adjacent to the inner surface of the pump housing and extends from the first port to the second port.

16. A method comprising:
subjecting a magnetic shape memory (MSM) element to a magnetic field of a permanent magnet, wherein the MSM element has first end, a second end, and a longitudinal axis that extends from the first end to the second end;
sweeping a first power level through a first electromagnet directed to the first end of the MSM element; and
sweeping a second power level through a second electromagnet directed to the second end of the MSM element.

17. The method of claim 16, wherein the magnetic field has a predominantly perpendicular component that is predominantly perpendicular to the longitudinal axis of the MSM element.

18. The method of claim 17, wherein increasing the first power level causes the predominantly perpendicular component of the magnetic field to move toward the second end and decreasing the first power level causes the predominantly perpendicular component to move toward the first end.

19. The method of claim 17, wherein increasing the second power level causes the predominantly perpendicular component of the magnetic field to move toward the first end and decreasing the second power level causes the predominantly perpendicular component to move toward the second end.

20. The method of claim 16, wherein the first power level and the second power level are swept at complementary power levels to cause continuous movement of a contracted portion of the MSM element along the longitudinal axis.
